(19) United States
(12) Patent Application Publication
(10) Pub. No.: US 2003/0051658 A1
(43) Pub. Date: Mar. 20, 2003

(54) Method and apparatus for controlling the oxygen concentration of a silicon single crystal, and method and apparatus for providing guidance for controlling the oxygen concentration

(76) Inventors: Shigemasa Nakagawa, Osaka (JP); Masato Tabuchi, Osaka (JP); Katsunori Nakashima, Tokyo (JP)

Correspondence Address: LORUSSO & LOUD, 3137 Mount Vernon Avenue, Alexandria, VA, 22305, US

(21) Appl. No.: 10/200,598

(22) Filed: Jul. 23, 2002

(30) Foreign Application Priority Data
Jul. 27, 2001 (JP) 227031
Jul. 27, 2001 (JP) 227032

(51) Int. Cl. C30B 15/00; C30B 21/06; C30B 27/02; C30B 28/10; C30B 30/04

(52) U.S. Cl. 117/13

(57) ABSTRACT

In a method/apparatus for controlling the oxygen concentration of a silicon single crystal during a process of growing it using the CZ method, and in a method/apparatus for providing guidance for controlling the oxygen concentration, influence coefficients indicating the degrees of influence of control factors on the oxygen concentration are determined on the basis of data of silicon single crystals actually grown in the past, and an optimum profile of a control factor is determined through learning by modifying the profile employed in the reference batch so as to minimize the deviation of the oxygen concentration, thereby automatically setting the control factors in the growth process in accordance with the optimized profile. To control the oxygen concentration of the silicon single crystal, guidance information is provided which indicates the manner of adjusting the growth process parameters such as a crucible rotation speed and a pressure in the furnace during the process of growing the silicon single crystal. The confidence level for the profiles of the growth process parameters is evaluated, and the confidence level or the evaluation value is presented together with the guidance information on the profiles of the growth process parameters.

### BACKGROUND OF THE INVENTION

1. Field of the Invention

The present invention relates to a technique of controlling the oxygen concentration in a silicon single crystal, and more particularly, to a method/apparatus for controlling the oxygen concentration of a silicon single crystal during a process of growing it using the Czochralski (CZ) method and also to a method/apparatus for providing guidance for controlling the oxygen concentration,

2. Description of the Related Art

There are various known methods for growing a single crystal used as a semiconductor material. A specific example is the CZ method. FIG. 1 is a cross-sectional view schematically illustrating a crystal growing apparatus used to pull up a single crystal by the CZ method. In this figure, reference numeral 12 denotes a vessel. A chamber 11 is formed with the vessel 12, wherein the chamber 11 includes, in its upper part, a cylindrical-shaped upper chamber 11a. A quartz crucible 13a in the form of a cylinder with a closed bottom end is disposed in the center of the chamber 11. The quartz crucible 13a is charged with molten silicon 15. The quartz crucible 13a is surrounded by a graphite crucible 13b in the form of a cylinder with a closed bottom end. The quartz crucible 13a and the graphite crucible 13b form a crucible 13.

A driving apparatus (not shown) is connected to the lower part of the crucible 13 through a rotating shaft 18 such that the crucible 13 can be rotated and moved upward or downward at predetermined rates by the driving apparatus. A heater 14 is disposed concentrically outside the crucible 13 such that a raw material of silicon charged in the quartz crucible 13a can be heated by the heater 14 so as to form a melt 15 of silicon.

A wire 16c serving as a part of a puller 16 is suspended along the central axis of the crucible 13, and a seed crystal 16a is held by a seed crystal holder 16b disposed at the end of the wire 16c. The wire 16c is rotated and pulled up by a winder 16d. The lower part of the vessel 12 is connected to a vacuum pump (not shown) through an opening 19 so that the pressure in the chamber 11 (hereinafter, referred to as a pressure in the furnace) can be set at a predetermined pressure by the vacuum pump.

The upper chamber 11a is connected to a gas supply system (not shown) such that an inert gas, such as Ar, can be supplied from the gas supply system into the chamber 11 at a predetermined flow rate through the upper chamber 11a. A crystal growing apparatus 20 is formed by the chamber 11, the crucible 13, the heater 14, the pulling-up apparatus 16, the driving apparatus, the vacuum pump, and the gas supply system.

A silicon single crystal can be grown by the CZ method using the above-described crystal growing apparatus 20 as follows. First, a silicon raw material is charged into the quartz crucible 13a, and the inside of the chamber 11 is evacuated by the vacuum pump to a predetermined pressure. An inert gas is then supplied at a predetermined flow rate into the chamber 11 from the gas supply system, and a current is passed through the heater 14 to heat the crucible 13 thereby forming the melt 15. Thereafter, the seed crystal 16a held on the end of the seed crystal holder 16b suspended by the wire 16c is brought into contact with the surface of the melt 15, and the wire 16c is wound up by the winder 16d while rotating the crucible 13 and the puller 16 at a predetermined rotation speed, thereby solidifying the melt 15 so as to grow a silicon single crystal 17.

One of parameters that should be evaluated for the grown silicon single crystal 17 is the concentration of oxygen contained in the crystal 17. Oxygen contained in a silicon wafer functions to capture impurities in the silicon wafer (this function is called “intrinsic gettering”). Thus, if a proper amount of oxygen is contained in the silicon single crystal 17, the performance of a semiconductor device is improved. However, if the oxygen concentration is too high, a crystal defect can be introduced into a device region. For the above reason, it is important to control the oxygen concentration in the crystal within a predetermined range.

In the above process, a source of oxygen is the quartz crucible 13a. Oxygen dissolved from quartz crucible 13a into the melt 15 is partially incorporated into the single crystal 17 through a liquid-solid interface. Thus, in the conventional CZ technique, as the silicon single crystal 17 is pulled up, the height of the silicon melt 15 decreases and thus the contact area between the melt 15 and the quartz crucible 13a decreases. As a result, the amount of oxygen dissolved from the quartz crucible 13a into the silicon melt 15 decreases, and thus the oxygen concentration of the crystal tends to decrease. Consequently, the oxygen concentration of the silicon single crystal 17 tends to become not uniform in its axial direction (pulling-up direction).

Various methods have been proposed to deal with the above problem. For example, Japanese Examined Patent Application Publication No. 2-44799 discloses a technique of changing the rotation speed of the crucible during the growing process. Japanese Unexamined Patent Application Publication No. 1-160892 discloses a technique in which a gap between a guide element and a silicon melt, through which an inert gas is supplied into a furnace, is reduced in accordance with the length of a grown silicon single crystal. In a technique disclosed in Japanese Unexamined Patent Application Publication No. 1-160893, the flow rate of an inert gas flowing between a guide member and the surface of molten silicon is increased continuously in accordance with the length of a silicon single crystal grown. Japanese Unexamined Patent Application Publication No. 3-159986 discloses a technique in which, as the solidification ratio of a silicon single crystal (the length of the grown crystal) increases, the pressure in a chamber is increased or the flow rate of an inert gas is reduced.

In a technique disclosed in Japanese Unexamined Patent Application Publication No. 6-172081, the relationship between the oxygen concentration of a crystal and growth process parameter is formulated, the growth process parameters are determined by means of fitting, and the oxygen concentration of the crystal is controlled in accordance with the determined growth process parameters.

In any above-described technique of controlling the oxygen concentration of a crystal, influences of time-dependent changes in characteristic due to, for example, degradation of a component of the crystal growing apparatus upon the oxygen concentration of the crystal are not taken into account. That is, changes in influencing factors, due to changes in parameters, on the oxygen concentration of a crystal are not taken into account. Therefore, when many crystals are grown, the oxygen concentrations of crystals can gradually deviate from a target value.

In order to eliminate the effects of changes in various parameters or factors with time on the oxygen concentration, it is necessary to learn the measured oxygen concentration of already-grown crystals and determine the crystal growth conditions or parameters for a next run on the basis of knowledge acquired via the learning.

However, the learning is time consuming and difficult for a human operator. Thus, only a human operator having high skill and good knowledge can determine the growth conditions or parameters.

In a technique disclosed in Japanese Unexamined Patent Application Publication No. 9-59084, to control the oxygen concentration of a crystal, correction values applied to a mathematical expression indicating the dependence of the oxygen concentration of a crystal on control factors such as a crucible rotation speed are classified into those caused by degradation of parts of an apparatus, a change in the type of crystal, and other unknown factors, and the mathematical expression is corrected in accordance with the difference between a measured oxygen concentration and an expected value thereby better controlling the oxygen concentration. This technique has been further improved in Japanese Unexamined Patent Application Publication No. 11-322485. In this further improved technique, when crystals are grown using various different apparatus, corrections described above are made taking into account apparatus-to-apparatus differences in the degree of influence of corrections made in response to a change in the crystal type upon the oxygen concentration.

However, in the techniques disclosed in Japanese Unexamined Patent Application Publication No. 9-59084 or 11-322485, the influence coefficients indicating the degree of influence of growth process parameters on the oxygen concentration are fixed in the mathematical expression, although the influence coefficients actually vary with time due to, for example, degradation of a part of an apparatus. Furthermore, to modify the mathematical relationship on the basis of the difference between the measured oxygen concentration and the predicted value, the learning has to be performed many times until the oxygen concentration reaches the target value. This is very inefficient.

In the above-described methods of controlling the oxygen concentration of crystals, although recommended profiles of crystal growth process parameters such as the crucible rotation speed, the inert gas flow rate, the furnace inert-pressure, and the melt level to be adjusted in the crystal growth process are presented, the degree of the confidence for the recommended profiles of the growth process parameters, which are expected to be adjusted in response to the change in the pulling-up ratio, is not presented to the human operator.

Therefore, when the degree of confidence is low, if the recommended profile is directly applied, the oxygen concentration can often deviate from the specified range. This is a serious problem in production of crystals. The human operator may evaluate the recommended profile and may modify it if necessary. However, in this case, the human operator is required to evaluate the recommended profile each time it is presented. This is very troublesome and time consuming for the human operator.

### SUMMARY OF THE INVENTION

In view of the above, it is an object of the present invention to provide a method and apparatus for controlling the oxygen concentration of a silicon single crystal and also provide a method and apparatus for provide guidance for controlling the oxygen concentration, in which a database is searched to select a reference batch, depending on a growth condition to be employed in growing a silicon single crystal the next time; an influence coefficient indicating the degree of influence of a control factor on the oxygen concentration of a crystal is determined for each run, from a growth process condition employed in the reference batch and the deviation of a measured oxygen concentration from a target value of the oxygen concentration; and learning is performed on the profile of control factors in the growth process to obtain an optimum profile by modifying the profile of the control factors employed in the reference batch so as to minimize the deviation of the oxygen concentration from the target value taking into account the updated influence coefficients; thereby minimizing the deviation of the oxygen concentration of single crystals, which can occur due to time-dependent changes in characteristics/conditions of an crystal growth apparatus/environment, caused by, for example degradation in a part of the crystal growth apparatus, thereby ensuring that the oxygen concentration of the grown silicon single crystal is easily controlled within a specified range, and thus making it possible to grow a single crystal having high quality with a high production yield.

According to an aspect of the present invention, to achieve the above object, there is provided a method of controlling the oxygen concentration of a silicon single crystal grown using the Czochralski method, comprising the step of, when a growth process condition to be employed in growing a silicon single crystal the next time is determined on the basis of a growth process condition actually used in the past in growing a silicon single crystal, making a correction using an influence coefficient.

This method of controlling the oxygen concentration of a silicon single crystal makes it possible to easily control the oxygen concentration of a grown silicon single crystal within a specified range over the whole length of the crystal and to minimize the deviation of the oxygen concentration of single crystals, which can occur due to time-dependent changes in characteristics/conditions of a crystal growth apparatus/environment. Thus, it becomes possible to grow a single crystal having high quality with a high production yield.

According to another aspect of the present invention, there is provided a method of controlling the oxygen concentration of a silicon single crystal grown using the Czochralski method, comprising the steps of: preparing a database including data indicating a growth process condition, depending on a crystal length, employed in an already-grown batch and also including data indicating a measured oxygen concentration thereof; searching the database to select a reference batch, depending on a growth condition to be employed in growing a silicon single crystal the next time; reversely determining an influence coefficient indicating the degree of influence of a control factor on the oxygen concentration of a crystal, from a growth process condition employed in the reference batch and the deviation of a measured oxygen concentration from a target value of the oxygen concentration, thereby correcting the influence coefficient; performing learning on the profile of control factors in the growth process to obtain an optimum profile by modifying the profile of the control factors employed in the reference batch so as to minimize the deviation of the oxygen concentration of the reference batch taking into account the corrected influence coefficients; and determining the growth condition to be actually used in growing the silicon single crystal the next time, in accordance with the optimized profile.

In this method of controlling the oxygen concentration of a silicon single crystal, influence coefficients indicating the degrees of influence of control factors on the oxygen concentration are determined on the basis of data of silicon single crystals actually grown in the past; learning is performed on the profile of control factors in the growth process to obtain an optimum profile by modifying the profile of the control factors employed in a reference batch so as to minimize the deviation of the oxygen concentration of the reference batch from the target value taking into account the determined influence coefficients; and a silicon single crystal is grown in accordance with the optimized profile of the control factors. This method makes it possible to easily control the oxygen concentration of a grown silicon single crystal within a specified range over the whole length of the crystal, and to minimize the deviation of the oxygen concentration of single crystals, which can occur due to time-dependent changes in characteristics/conditions of a crystal growth apparatus/environment. Thus, it becomes possible to grow a single crystal having high quality with a high production yield.

According to another aspect of the present invention, there is provided a method of controlling the oxygen concentration of a silicon single crystal grown using the Czochralski method, comprising the steps of preparing a database including data indicating a growth process condition, depending on a crystal length, employed in an already-grown batch and also including data indicating a measured oxygen concentration thereof; searching the database to select a reference batch, depending on a growth condition to be employed in growing a silicon single crystal the next time; reversely determining an influence coefficient indicating the degree of influence of a control factor on the oxygen concentration of a crystal, from a growth process condition employed in the reference batch and the deviation of a measured oxygen concentration from a target value of the oxygen concentration, thereby correcting the influence coefficient; performing learning on the profile of a control factor in the growth process to obtain an optimum profile by modifying the profile of the control factor employed in the reference batch so as to minimize the deviation of the oxygen concentration taking into account the corrected influence coefficient; and determining the growth condition to be actually used in growing the silicon single crystal the next time in accordance with the optimized profile.

In this method of controlling the oxygen concentration of a silicon single crystal, influence coefficients indicating the degrees of influence of control factors on the oxygen concentration are reversely determined on the basis of data of silicon single crystals actually grown in the past; learning is performed on the profile of control factors in the growth process to obtain an optimum profile by modifying the profile of the control factors employed in a reference batch so as to minimize the deviation of the oxygen concentration of the reference batch from the target value taking into account the reversely determined influence coefficients; and a silicon single crystal is grown in accordance with the optimized profile of the control factors. This method makes it possible to easily control the oxygen concentration of a grown silicon single crystal within a specified range over the whole length of the crystal, and to minimize the deviation of the oxygen concentration of single crystals, which can occur due to time-dependent changes in characteristics/conditions of an crystal growth apparatus/environment. Thus, it becomes possible to grow a single crystal having high quality with a high production yield.

In the above method of controlling the oxygen concentration of a silicon single crystal according to the present invention, as for the crystal-length-dependent growth process condition actually used in the past, one or more conditions may be selected from a group consisting of a crystal-length-dependent crucible rotation speed actually employed, a crystal-length-dependent pressure in the furnace actually employed, a crystal-length-dependent inert gas flow rate actually employed, a crystal-length-dependent melt level actually employed, and a crystal-length-dependent crystal rotation speed actually employed. That is, in this method in which, as for the crystal-length-dependent growth process condition actually used in the past, one or more conditions are selected from a group consisting of a crystal-length-dependent crucible rotation speed actually employed, a crystal-length-dependent pressure in the furnace actually employed, a crystal-length-dependent inert gas flow rate actually employed, a crystal-length-dependent melt level actually employed, and a crystal-length-dependent crystal rotation speed actually employed, if the deviation of the oxygen concentration cannot be reduced to a sufficiently low level by adjusting a first growth process parameter, a second growth process parameter and/or a third growth process parameter are adjusted so as to further reduce the deviation of the oxygen concentration to a sufficiently low level, thereby ensuring that the silicon single crystal having high quality is grown with a high production yield.

In the above method of controlling the oxygen concentration of a silicon single crystal according to the present invention, a relational database may be employed as the database including data indicating growth process conditions actually employed in the past and also including data indicating measured oxygen concentrations.

If such a relational database is employed as the database including data indicating growth process conditions actually employed in the past and also including data indicating measured oxygen concentrations, it becomes easy to build the database, and the resultant database can be easily accessed by other systems using the SQL language.

Alternatively, a database using flat files may be employed as the database including data indicating growth process conditions actually employed in the past and also including data indicating measured oxygen concentrations.

In the case where such a database using a flat file is employed as the database including data indicating growth process conditions actually employed in the past and also including data indicating measured oxygen concentrations, it becomes possible to build the database based on a peculiar algorithm so that the resultant database cannot be easily accessed by other systems thereby achieving high security.

According to still another aspect of the present invention, there is provided an apparatus for controlling the oxygen concentration of a silicon single crystal, comprising: a database including data indicating a growth process parameter employed in the past to grow a single crystal and also including data indicating the quality of the grown crystal; an influence coefficient calculator for determining, by means of calculation, an influence coefficient indicating the degree of influence of the growth process parameter on the oxygen concentration, on the basis of a measured oxygen concentration and the growth process parameter actually employed in the past; and a growth process parameter setting unit for calculating the profile of a growth process parameter such as a crucible rotation speed, a pressure in the furnace, or an inert gas flow rate to be employed in growing a silicon single crystal the next time.

In this apparatus for controlling the oxygen concentration of a silicon single crystal, influence coefficients indicating the degrees of influence of control factors on the oxygen concentration are determined on the basis of data of silicon single crystals actually grown in the past; learning is performed on the profile of control factors in the growth process to obtain an optimum profile by modifying the profile of the control factors employed in a reference batch so as to minimize the deviation of the oxygen concentration of the reference batch from the target value taking into account the determined influence coefficients; and a silicon single crystal is grown in accordance with the optimized profile of the control factors. This apparatus makes it possible to easily control the oxygen concentration of a grown silicon single crystal within a specified range over the whole length of the crystal, and to minimize the deviation of the oxygen concentration of single crystals, which can occur due to time-dependent changes in characteristics/conditions of an crystal growth apparatus/environment. Thus, it becomes possible to grow a single crystal having high quality with a high production yield.

It is another object of the present invention to provide a method/apparatus for providing guidance for controlling the oxygen concentration of a silicon single crystal, which indicates the manner of adjusting a growth process parameter such as a crucible rotation speed, an inert gas flow rate, a pressure in the furnace, or a melt level so as to control the oxygen concentration of the crystal to a specified level, wherein the confidence level for the profiles of the growth process parameter is determined from the confidence value, and the confidence level or the confidence value is presented together with the guidance information on the profile of the growth process parameter thereby reducing the amount of job performed by a human operator to evaluate the profile of the growth process parameter to be employed, and making it possible to control the oxygen concentration of the crystal within the specified range and thus ensuring that the silicon single crystal having high quality is grown with a high production yield.

According to an aspect of the present invention, to achieve the above object, there is provided a method of providing guidance for controlling the oxygen concentration of a silicon single crystal during a process of growing the silicon single crystal using the Czochralski method, in accordance with a method of controlling the oxygen concentration by determining a growth condition to be employed in growing a silicon single crystal the next time by means of modifying a growth condition actually employed in the past for a batch, said method comprising the step of presenting, as guidance information, a reference growth condition obtained by modifying the growth condition employed in the batch, and also presenting the level of confidence for the guidance information.

In this method of providing guidance for controlling the oxygen concentration of a silicon, a human operator can easily modify a crystal growth condition in accordance with the guidance information, because the confidence level is also presented together with the guidance information. This allows a reduction in the amount of job of the human operator, and ensures that a silicon single crystal having high quality is grown with a high production yield.

According to another aspect of the present invention, there is provided a method of providing guidance for controlling the oxygen concentration of a silicon single crystal during a process of growing the silicon single crystal by means of pulling up the crystal from a melt in a quartz crucible, said method comprising the steps of: preparing a database including data indicating a growth process condition, depending on a crystal length, employed in an already-grown batch and also including data indicating a measured oxygen concentration thereof; searching the database to select a reference batch, depending on a growth condition to be employed in growing a silicon single crystal the next time; modifying the growth condition of the reference batch on the basis of the growth condition of the reference batch and the deviation of the oxygen concentration from a target value of the oxygen concentration so as to eliminate the deviation of the oxygen concentration from the target value, thereby determining the growth condition to be actually used in growing the silicon single crystal the next time; evaluating the confidence level for the determined profile of the growth process parameter, on the basis of data of silicon single crystals actually grown in the past; and presenting the confidence level or the confidence value, together with the guidance information on the profile of the growth process parameter.

In this method of providing guidance for controlling the oxygen concentration of a silicon single crystal, learning is performed on the profile of control factors in the growth process to obtain an optimum profile by modifying the profile of the control factors employed in a reference batch so as to minimize the deviation of the oxygen concentration of the reference batch from the target value taking into account the reversely determined influence coefficients; and the confidence level or the confidence value for the determined profile of the growth parameter is presented, thereby reducing the amount of job performed by a human operator to evaluate the profile of the growth process parameter to be employed, and making it possible to control the oxygen concentration of the crystal within the specified range and thus ensuring that the silicon single crystal having high quality is grown with a high production yield.

According to still another aspect of the present invention, there is provided an apparatus for providing guidance for controlling the oxygen concentration of a silicon single crystal during a process of growing the silicon single crystal using the Czochralski method, said apparatus comprising: a database including data indicating a growth process parameter employed in the past to grow a single crystal and also including data indicating the quality of the grown crystal; a growth process parameter setting unit for calculating the profile of a growth process parameter such as a crucible rotation speed, a pressure in the furnace, or an inert gas flow rate to be employed in growing a silicon single crystal the next time; a confidence value calculator for calculating the confidence value for the profile of a growth process parameter calculated by the growth process parameter setting unit, on the basis of an environmental factor and statistical data; a confidence level evaluator for determining the confidence level by evaluating the confidence value calculated by the confidence value calculator; and a guidance output unit for presenting the confidence value or the confidence level for the profile of the growth parameter together with the profile of the growth process parameter.

In this apparatus for providing guidance for controlling the oxygen concentration of a crystal, learning is performed on the profile of control factors in the growth process to obtain an optimum profile by modifying the profile of the control factors employed in a reference batch so as to minimize the deviation of the oxygen concentration of the reference batch from the target value taking into account the reversely determined influence coefficients; and the confidence value or the confidence level for the determined profile of the growth parameter is presented to a human operator thereby reducing the amount of job performed by the human operator to evaluate the profile of the growth process parameter to be employed, and making it possible to control the oxygen concentration of the crystal within the specified range and thus ensuring that the silicon single crystal having high quality is grown with a high production yield.

### BRIEF DESCRIPTION OF THE DRAWINGS

FIG. 1 is a cross-sectional view schematically illustrating a crystal growing apparatus based on the CZ method, according to an embodiment of the present invention, wherein the apparatus has a structure similar to that according to a conventional technique;

FIG. 2 is a flow chart schematically illustrating a method of controlling the oxygen concentration of a crystal, according to an embodiment of the present invention;

FIG. 3 is a graph showing batch-to-batch variations in the crucible rotation speed, the pressure in the furnace, and the inert gas flow rate for the pulling-up ratio of 18.75% and 68.75%, and also a batch-to-batch variation in the oxygen concentration of crystals at the pulling-up ratio of 18.75% and 68.75%, grown using the method of controlling oxygen concentration of crystal according to the embodiment of the present invention;

FIG. 4 is a graph showing the oxygen concentration as a function of the pulling-up ratio, for a silicon single crystal grown by controlling the oxygen concentration according to the embodiment of the present invention;

FIG. 5 is a flow chart illustrating a method of providing guidance for controlling the oxygen concentration of a crystal, according to the present invention;

FIG. 6 is a diagram showing a manner of determining the value of a parameter α;

FIG. 7 is a graph showing batch-to-batch variations in a first growth process parameter and a second growth process parameter at the pulling-up ratio of 18.75% and 68.75%, which were evaluated to be high in confidence level (G5) by the method of providing guidance information on the control of the oxygen concentration of a crystal according to an embodiment of the present invention, and also showing a batch-to-batch variation in oxygen concentration of grown resultant crystals;

FIG. 8 is a graph showing the oxygen concentration as a function of the pulling-up ratio for a crystal grown using growth process parameters evaluated to be high in confidence level (G5) by the method of providing guidance for controlling the oxygen concentration of a crystal according to an embodiment of the present invention; and

FIG. 9 is a graph showing the oxygen concentration as a function of the pulling-up ratio for a crystal grown using growth process parameters evaluated to be low in confidence level (G1) by the method of providing guidance for controlling the oxygen concentration of a crystal according to an embodiment of the present invention.

### DESCRIPTION OF THE PREFERRED EMBODIMENTS

The method and apparatus for controlling the oxygen concentration of a silicon single crystal and the method and apparatus for providing guidance for controlling the oxygen concentration are described in further detail below with reference to preferred embodiments in conjunction with the accompanying drawing.

First Embodiment

A method and apparatus for controlling the oxygen concentration of a silicon crystal according to an embodiment of the present invention are described below with reference to the accompanying drawings. Similar parts to those according to the conventional technique are denoted by similar reference numerals.

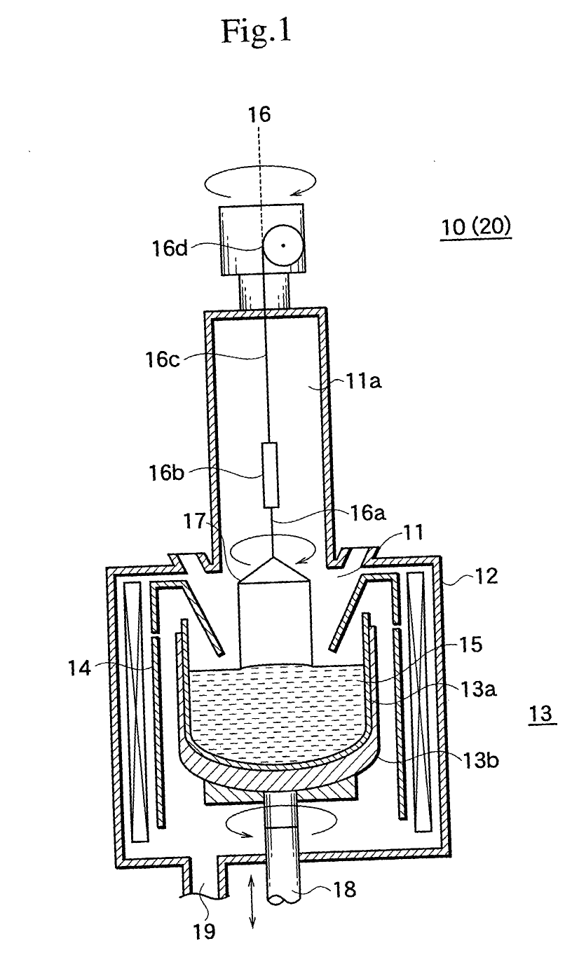

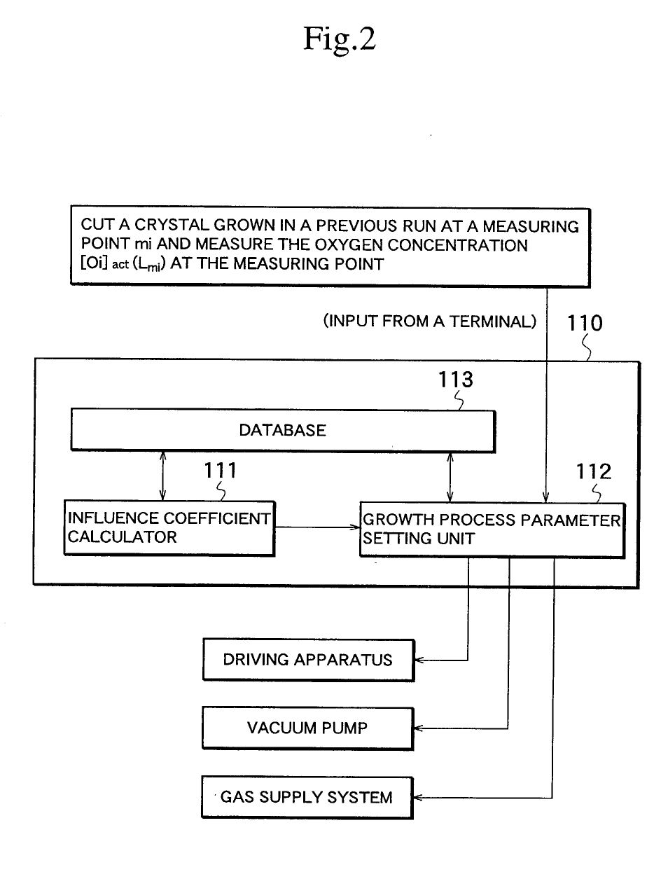

FIG. 1 is a cross-sectional view schematically illustrating a crystal growing apparatus used to grow a silicon single crystal while controlling the oxygen concentration of the silicon single crystal according to an embodiment of the present invention. A driving apparatus for driving a crucible 13, a vacuum pump connected to an opening 19, and an inert gas supplying system are connected to an oxygen concentration controller 110 including an influence coefficient calculator 111, a growth process parameter setting unit 112, and a database 113 as shown in FIG. 2.

The database 113 stores data indicating parameters which were employed in the past to grow single crystals and also stores data indicating the quality of the grown crystals. The database 113 may be easily built in the form of a relational database (RDB). In this case, the database 113 can be easily accessed by other systems using the SQL language. Instead of using a relational database (RDB), the database 113 may also be built using flat files on the basis of a direct access method or an index method. In this case, because the database 113 is based on its own peculiar algorithm, the database 113 can have high security, although it becomes difficult for another system to access the database 113.

The influence coefficient calculator 111 calculates influence coefficients of growth process parameters on the oxygen concentration, on the basis of the measured oxygen concentration data and growth process parameters actually employed. The growth process parameter setting unit 112 calculates the profiles of parameters to be employed to grow a next crystal, such as the rotation speed CRₙ₊₁ of the crucible, the pressure Pₙ₊₁ in the furnace, and the flow rate Qₙ₊₁ of the inert gas. The other parts are similar to those in the conventional crystal growing apparatus 20, and thus they are not described in further detail herein. Thus, a crystal growing apparatus 10 including the oxygen concentration controller 110 and other parts is formed in accordance with the present embodiment.

A process of growing a silicon single crystal using the crystal growing apparatus 10 constructed in the above-described manner while controlling the oxygen concentration of the silicon single crystal is described below with reference to FIG. 2. Before growing a next batch, a batch to be used as a reference batch in the next batch is determined from data stored in the database by taking into account the type of a single crystal to be grown and other conditions. More specifically, on the basis of crystal-type information (such as the serial number, the oxygen concentration specification, and the target value of the oxygen concentration) of the single crystal to be grown, the database is searched for already-grown batches that match the crystal type, and a list of all retrieved batches is produced. The retrieved batches are evaluated in terms of items described below, and the score is calculated for each evaluation item for each batch. A batch having a highest total score is employed as a reference batch.

J(1): Score calculated on the basis of whether the furnace number of a furnace used to grow a crystal in a batch is equal to that to be used.

J(2): Score calculated on the basis of the interval between the date when the previous crystal in the previous batch was grown and a date when a crystal is to be grown.

J(3): Score calculated on the basis of the difference in heater usage period.

J(4): Score calculated on the basis of heater replacement.

J(5): Score calculated on the basis of the difference in usage time of a part.

J(6): Score calculated on the basis of part replacement.

Total score W=ΣJ(i)

Thereafter, the measured oxygen concentration values [Oi]_{act} (Lₘᵢ) at measurement points mi of single crystals of the reference batch are extracted from the database. The extracted measured values [Oi]_{act} (Lₘᵢ) at pulling-up ratios Lₘᵢ for respective samples are input to the influence coefficient calculator 111 of the oxygen concentration controller 110. On the basis of the measured oxygen concentration values and growth process parameters, the influence coefficient calculator 111 calculates the influence coefficients of the growth process parameters, which are factors to be controlled, on the oxygen concentration.

The growth process parameter setting unit 112 calculates the profiles of growth process parameters to be employed in the next growing process, such as the rotation speed CR_{set,n+1} of the crucible, the pressure P_{set,n+1} in the furnace, and the flow rate Q_{set,n+1} of the inert gas, as described below.

In general, the oxygen concentration [Oi] of a silicon single crystal depends on the pulling-up ratio L, the rotation speed CR of the crucible, the pressure P in the furnace, the flow rate Q of the inert gas, the melt level GAP, the rotation speed SR of the crystal, the heater power HP, and the pulling-up speed FP. That is, the oxygen concentration [Oi] is given by Equation (1) described below.

[Oi](L)=f(L, CR, P, Q, GAP, SR, HP, FP) (1)

When a crystal is actually pulled up, the growth process parameters to be controlled are given in the form of profiles indicating the values of parameters as a function of the pulling-up ratio L, and the crystal is pulled up in accordance with the given profiles.

Specific examples of profiles of parameters are:

profile of the rotation speed of the crucible: CR=CR(L),

profile of the pressure in the furnace: P=P(L),

profile of the flow rate of the inert gas: Q=Q(L),

profile of the melt level: GAP=GAP(L),

profile of the rotation speed of crystal: SR=SR(L),

profile of the heater power: HP=HP(L), and

profile of the pulling-up speed: FP=FP(L).

In general, the growth process parameters described above can influence the oxygen concentration, although some of these parameters are not necessary to be varied depending on the pulling-up ratio L. To control the oxygen concentration, the manner of determining the profiles of the respective growth process parameters is important. In the present invention, the profiles to be employed in a crystal growth process are determined on the basis of data of a reference batch in which the crystal have been grown. When a reference batch Bn is given, profiles of parameters of the reference batch Bn, that is, CR_{act,Bn}(L), P_{act,Bn}(L), Q_{act,Bn}(L), GAP_{act,Bn}(L), SR_{act,Bn}(L), HP_{act,Bn}(L), and FP_{act,Bn}(L), are employed in the next growth process as reference profiles CR_{ref}(L), P_{ref}(L), Q_{ref}(L), GAP_{ref}(L), SR_{ref}(L), HP_{ref}(L), and FP_{ref}(L).

That is, the respective reference profiles are given as follows:

reference profile of the rotation speed of the crucible: CR_{ref}(L)=CR_{act,Bn}(L)

reference profile of the pressure in the furnace: P_{ref}(L)=P_{act,Bn}(L),

reference profile of the flow rate of the inert gas: Q_{ref}(L)=Q_{act,Bn}(L),

reference profile of the melt level: GAP_{ref}(L)=GAP_{act,Bn}(L),

reference profile of the rotation speed of crystal: SR_{ref}(L)=SR_{act,Bn}(L),

reference profile of the heater power: HP_{ref}(L)=HP_{act,Bn}(L), and

reference profile of the pulling-up speed: FP_{ref}(L)=FP_{act,Bn}(L).

The measured oxygen concentration values [Oi]_{act} for the reference batch Bn are stored in the database, and a set of a measurement position (=pulling-up ratio), a measured oxygen concentration, and a target value [Oi]ₐᵢₘ of the oxygen concentration is obtained for various measurement positions as described below.

{Lₘ₁, [Oi]_{act,Bn}(1), [Oi]_{aim,Bn}(1)},

{Lₘ₂, [Oi]_{act,Bn}(2), [Oi]_{aim,Bn}(2)},

{Lₘ₃, [Oi]_{act,Bn}(3), [Oi]_{aim,Bn}(3)}, and so on.

The oxygen concentration deviation Δ[Oi]ₑᵣᵣ, that is, the measured oxygen concentration−the target value of oxygen concentration, is given by Equation (2) described below.

Δ[Oi]_{err,Bn}(i)=[Oi]_{act,Bn}(i)−[Oi]_{aim,Bn}(i) (1≦i≦n) (2)

When the oxygen concentration [Oi] of a silicon single crystal is a function of the pulling-up ratio L, the crucible rotation speed CR, the pressure in the furnace P, the inert gas flow rate Q, the melt level GAP, the crystal rotation speed SR, the heater power HP, and the pulling-up speed FP, the change in the oxygen concentration [Oi] is given by Equation (3) described below.

$$Δ f ( L , CR , P , Q , GAP , SR , HP , FP ) = \frac{\partial f}{\partial L} Δ L + \frac{\partial f}{\partial CR} Δ CR + \frac{\partial f}{\partial P} Δ P + \frac{\partial f}{\partial Q} Δ Q + \frac{\partial f}{\partial GAP} Δ GAP + \frac{\partial f}{\partial SR} Δ SR + \frac{\partial f}{\partial HP} Δ HP + \frac{\partial f}{\partial FP} \qquad ( 3 )$$

Although various growth process parameters must be controlled to control the oxygen concentration of a silicon single crystal, only three growth process parameters, the crucible rotation speed CR, the pressure in the furnace P, and the inert gas flow rate Q are taken by way of example as the first, second, and third growth process parameters, respectively, in the following discussion. First, the oxygen concentration deviation is tried to be eliminated by optimizing the crucible rotation speed by means of learning. This can be achieved when Equation (4) is satisfied, and thus a compensation amount ΔCR(i) for the crucible rotation speed is given by Equation (5). In Equations (4) and (5), ∂f/∂CR is the influence coefficient indicating the degree of influence of the crucible rotation speed on the oxygen concentration of a crystal. This influence coefficient is experimentally determined in advance or calculated for each batch in a manner described later.

$$\begin{matrix}- {Δ [ Oi ]}_{err , Bn} ( i ) = \frac{\partial f}{\partial CR} Δ CR & ( 4 ) \\ Δ CR ( i ) = - \frac{{Δ [ Oi ]}_{err , Bn} ( i )}{\frac{\partial f}{\partial CR}} & ( 5 )\end{matrix}$$

Herein, ΔCR(i) (i=1, 2, 3, . . . , n) is given only for discrete values of the pulling-up ratio L. Therefore, the compensation value ΔCR(L)(0≦L≦1) for the profile of the growth process parameter CR(L) depending on the pulling-up ratio L is given by a polygonal-line function of the pulling-up ratio L obtained by connecting ΔCR(i) (i=1, 2, 3, . . . , n) with a polygonal line. In particular, ΔCR(Lₘᵢ)=ΔCR(i) for L=Lₘᵢ.

In the following description, the reference profile of the crucible rotation speed CR_{ref}(L) is assumed to be given by a polygonal-line function. More specifically, the reference profile of the crucible rotation speed takes values of CR₀, CR₁, CR₂, . . . , CR_{N} when the pulling-up ratio L has values of L₀ (=0), L₁, L₂, . . . , L_{N} (=1), respectively. However, when the pulling-up ratio L has a value other than the above, the reference profile of the crucible rotation speed takes a value calculated by means of linear interpolation.

Herein, if the optimized profile of the crucible rotation speed to be employed in the crystal growing process is represented by CR′(L), and if the values thereof for discrete values of L are represented by:

CR₀′=CR₀+δCR₀,

CR₁′=CR₁+δCR₁,

CR₂′=CR₂+δCR₂,

CR_{N}′=CR_{N}+δCR_{N},

then the optimum profile is obtained by determining the values of δCR₀, δCR₁, δCR₂, . . . . , δCR_{N} so that Equation (6) has a minimum value or a value smaller than a predetermined value ε_{CR}.

$${J}_{CR} = {\int }_{0}^{1} {\{ ( {CR}_{act , Bn} ( L ) + Δ CR ( L ) ) - {CR}^{′} ( L ) \}}^{2} ⅆ L \qquad ( 6 )$$

Herein, we introduce a function δCR_{modify}(L) which takes values of δCR₀, δCR₁, δCR₂, . . . , δCR_{N} when the pulling-up ratio L has values of L₀ (=0), L₁, L₂, . . . , L_{N} (=1), and which takes linearly-interpolated values for the other values of the pulling-up ratio L. The growth process parameter setting unit 112 determines the profile CR_{set,n+1}(L) of the crucible rotation speed to be employed in the crystal growth process in accordance with Equation (7) described below.

CR_{set,n+1}(L)=CR_{act,Bn}(L)+G_{CR}(L)×δCR_{modify}(L) (7)

where G_{CR}(L) is a learning control gain (0≦G_{CR}(L)≦1).

Herein, upper and lower limits are predetermined for CR_{set,n+1}(L), δC_{modify}(L), and the differential coefficient ∂CR_{set,n+1}(L)/∂L of CR_{set,n+1}(L) with respect to the pulling-up ratio. If the deviation of the oxygen concentration cannot be completely compensated for by controlling the crucible rotation speed because of the above limitations on values, the deviation is further compensated for by controlling the pressure in the furnace P in the next step.

To eliminate the oxygen concentration deviation by optimizing the pressure in the furnace, Equation (8) must be satisfied. Thus a compensation amount ΔP(i) for the pressure in the furnace is given by Equation (9). In Equations (8) and (9), ∂f/∂P is the influence coefficient indicating the degree of influence of the pressure in the furnace on the oxygen concentration of a crystal. This influence coefficient is experimentally determined in advance or calculated for each batch in a manner described later.

$$\begin{matrix}- {Δ [ Oi ]}_{err , Bn} ( i ) = \frac{\partial f}{\partial P} Δ P + \frac{\partial f}{\partial CR} δ {CR}_{modify} ( {L}_{mi} ) & ( 8 ) \\ Δ P ( i ) = - \frac{{Δ [ Oi ]}_{err , Bn} ( i ) + \frac{\partial f}{\partial CR} δ {CR}_{modify} ( {L}_{mi} )}{\frac{\partial f}{\partial P}} & ( 9 )\end{matrix}$$

Herein, ΔP(i) (i=1, 2, 3, . . . , n) is given only for discrete values of the pulling-up ratio L. Therefore, the compensation value ΔP(L)(0>L≦1) for the profile of the growth process parameter P(L) depending on the pulling-up ratio L is given by a polygonal-line function of the pulling-up ratio L obtained by connecting ΔP(i) (i=1, 2, 3, . . . , n) with a polygonal line. In particular, ΔP(L)=ΔP(i) for L=Lₘᵢ.

In the following discussion, it is assumed that the reference profile of the pressure in the furnace P_{ref}(L) is given by a polygonal-line function. That is, P_{ref}(L) takes values of P₀, P₁, P₂, . . . , P_{N} when the pulling-up ratio L has values of L₀ (=0), L₁, L₂, . . . , L_{N} (=1), and P_{ref}(L) takes linearly interpolated values in any interval.

Herein, if the optimized profile of the pressure in the furnace to be employed in the crystal growing process is represented by P′(L), and if the values thereof for discrete values of L are represented by:

P₀′=P₀+δP₀,

P₁′=P₁+δP₁,

P₂′=P₂+δP₂,

P_{N}′=P_{N}+δP_{N},

then the optimum profile is obtained by determining the values of δP₀, δP₀, δP₂, . . . , δP_{N} so that Equation (10) has a minimum value or a value smaller than a predetermined value ε_{P}.

$${J}_{P} = {\int }_{0}^{1} {\{ ( {P}_{act , Bn} ( L ) + Δ P ( L ) ) - {P}^{′} ( L ) \}}^{2} ⅆ L \qquad ( 10 )$$

Herein, we introduce a function δΔP_{modify}(L) which takes values of δP₀, δP₁, δP₂, . . . , δP_{N} when the pulling-up ratio L has values of L₀ (=0), L₁, L₂, . . . , L_{N} (=1), and which takes linearly-interpolated values in any interval. The growth process parameter setting unit 112 determines the profile P_{set,n+1}(L) of the pressure in the furnace to be employed in the next crystal growth process in accordance with Equation (11) described below.

P_{set,n+1}(L)=P_{act,Bn}(L)+G_{P}(L)×δP_{modify}(L) (11)

where G_{P}(L) is a learning control gain (0≦G_{P}(L)<1).

Herein, upper and lower limits are predetermined for P_{set,n+1}(L), δP_{modify}(L), and the differential coefficient ∂P_{set,n+1}(L)/ ∂L of P_{set,n+1}(L) with respect to the pulling-up ratio. If the deviation of the oxygen concentration cannot be completely compensated for by controlling the pressure in the furnace because of the above limitations on values, the deviation is further compensated for by controlling the inert gas flow rate in the next step.

To eliminate the oxygen concentration deviation by optimizing the inert gas flow rate, Equation (12) must be satisfied. Thus a compensation amount ΔQ(i) for the inert gas flow rate is given by Equation (13). In Equations (12) and (13), ∂f/∂Q is the influence coefficient indicating the degree of influence of the inert gas flow rate on the oxygen concentration of a crystal. This influence coefficient is experimentally determined in advance or calculated for each batch in a manner described later.

$$\begin{matrix}- {Δ [ Oi ]}_{err , Bn} ( i ) = \frac{\partial f}{\partial Q} Δ Q + \frac{\partial f}{\partial CR} δ {CR}_{modify} ( {L}_{mi} ) + \frac{\partial f}{\partial P} δ {P}_{modify} ( {L}_{mi} ) & ( 12 ) \\ Δ Q ( i ) = - \frac{{Δ [ Oi ]}_{err , Bn} ( i ) + \frac{\partial f}{\partial CR} δ {CR}_{modify} ( {L}_{mi} ) + \frac{\partial f}{\partial P} δ {P}_{modify} ( {L}_{mi} )}{\frac{\partial f}{\partial Q}} & ( 13 )\end{matrix}$$

Herein, ΔQ(i) (i=1, 2, 3, . . . , n) is given only for discrete values of the pulling-up ratio L. Therefore, the compensation value ΔQ(L)(0≦L≦1) for the profile of the growth process parameter Q(L) depending on the pulling-up ratio L is given by a polygonal-line function of the pulling-up ratio L obtained by connecting ΔQ(i) (i=1, 2, 3, . . . , n) with a polygonal line. In particular, ΔQ(Lₘᵢ)=ΔQ(i) for L=Lₘᵢ.

In the following description, the reference profile of the inert gas flow rate Q_{ref}(L) is assumed to be given by a polygonal-line function. More specifically, Q_{ref}(L) takes values of Q₀, Q₁, Q₂, . . . , Q_{N} when the pulling-up ratio L has values of L₀ (=0), L₁, L₂, . . . , L_{N} (=1), respectively. However, when the pulling-up ratio L has a value other than the above, Q_{ref}(L) takes a value calculated by means of linear interpolation.

Herein, if the optimized profile of the inert gas flow rate to be employed in the crystal growing process is represented by Q′(L), and if the values thereof for discrete values of L are represented by:

Q₀′=Q₀+δQ₀,

Q₁′=Q₁+δQ₁,

Q₂′=Q₂+δQ₂,

Q_{N}′=Q_{N}+δQ_{N},

then the optimum profile is obtained by determining the values of δQ₀, δQ₁, δQ₂, . . . , δQ_{N} so that Equation (14) has a minimum value or a value smaller than a predetermined value ε_{Q}.

$${J}_{Q} = {\int }_{0}^{1} {\{ ( {Q}_{act , Bn} ( L ) + Δ Q ( L ) ) - {Q}^{′} ( L ) \}}^{2} ⅆ L \qquad ( 14 )$$

Herein, we introduce a function δQ_{modify}(L) which takes values of δQ₀, δQ₁, δQ₂, . . . , Q_{N} when the pulling-up ratio L has values of L₀ (=0), L₁, L₂, . . . , L_{N} (=1), and which takes linearly-interpolated values for the other values of the pulling-up ratio L. The growth process parameter setting unit 112 determines the profile Q_{set,n+1}(L) of the inert gas flow rate to be employed in the next crystal growth process in accordance with Equation (15) described below.

Q_{set,n+1}(L)=Q_{set,Bn}(L)+G_{Q}(L)×δQ_{modify}(L) (15)

where G_{Q}(L) is a learning control gain (0≦G_{Q}(L)≦1).

Herein, upper and lower limits are predetermined for Q_{set,n+1}(L), δQ_{modify}(L), and the differential coefficient ∂Q_{set,n+1}(L)/∂L of Q_{set,n+1}(L) with respect to the pulling-up ratio.

After determining the growth process parameters as described above, the inside of the chamber 11 is evacuated by the vacuum pump to a predetermined pressure, and an inert gas is supplied at a predetermined flow rate into the chamber 11 from the gas supply system. A current is then passed through the heater 14 to heat the crucible 13 thereby forming the melt 15. Thereafter, the seed crystal 16a held on the end of the seed crystal holder 16b suspended by the wire 16c is brought into contact with the surface of the melt 15, and the wire 16c is wound up by the winder 16d while rotating the crucible 13 and the puller 16 at a predetermined rotation speed, thereby solidifying the melt 15 so as to grow a silicon single crystal 17.

In the example described above, the crucible rotation speed, the pressure in the furnace, and the inert gas flow rate are respectively employed as the first growth process parameter, the second growth process parameter, and the third growth process parameter. Note that the order of controlling the parameters is not limited to that described above, but another growth process parameter may also be employed.

In the example described above, the influence coefficients indicating the degrees of influence of the operating factors (the crucible rotation speed, the pressure in the furnace, and the inert gas flow rate) on the oxygen concentration of a crystal are determined in advance. Alternatively, they may be determined for each batch as described below.

First, the following parameters are extracted:

actual profile of the crucible rotation speed of a previous batch (reference batch Bn): CR_{act,Bn}(L),

actual profile of the pressure in the furnace of the previous batch (reference batch Bn): P_{act,Bn}(L),

actual profile of the inert gas flow rate of the previous batch (reference batch Bn): Q_{act,Bn}(L),

measured oxygen concentration of the previous batch (reference batch Bn): (L_{Bn,mi}, [Oi]_{act,Bn}(i)) (i=1, . . . , n)

actual profile of the crucible rotation speed of a batch (reference batch Bn−1) preceding the previous batch: CR_{act,Bn-1}(L)

actual profile of the pressure in the furnace of the batch (reference batch Bn−1) preceding the previous batch: P_{act,Bn-1}(L)

actual profile of the inert gas flow rate of the batch (reference batch Bn−1) preceding the previous batch: Q_{act,Bn-1}(L)

measured oxygen concentration of the batch (reference batch Bn−1) preceding the previous batch: (L_{Bn-1,mi}, [Oi]_{act,Bn-1}(i)) (i=1, . . . , k)

One or more representative points Lₘᵢ(i=1, . . . , K) of the pulling-up ratio are selected, and the values of the respective growth process parameters at the representative points are determined from the profiles described above. For example, the values can be determined by means of interpolation. The measured oxygen concentration at the representative points are also determined in a similar manner.

Thereafter, the following values are determined:

δCR_{act}(Lₘᵢ)=CR_{act,Bn}(Lₘᵢ)−CR_{act,Bn-1}(Lₘᵢ)

δP_{act}(Lₘᵢ)=P_{act,Bn}(Lₘᵢ)−P_{act,Bn-1}(Lₘᵢ)

δQ_{act}(Lₘᵢ)=Q_{act,Bn}(Lₘᵢ)−Q_{act,Bn-1}(Lₘᵢ)

δ[Oi]_{act}(Lₘᵢ)=[Oi]_{act,Bn}(Lₘᵢ)−[Oi]_{act,Bn-1}(Lₘᵢ)

Herein, the influence coefficients (Δ[Oi]/ΔCR))_{act}, (Δ[Oi]/ΔP)_{act}, and (Δ[Oi]/ΔQ)_{act} are determined so that

Equation (16) has a minimum value or a value smaller than a predetermined value εₑₛₜ.

$$J = {\sum }_{i = 1}^{K} {\{ \begin{matrix}δ {CR}_{act} ( {L}_{mi} ) \cdot {( \frac{Δ [ Oi ]}{Δ CR} )}_{act} + δ {P}_{act} ( {L}_{mi} ) \cdot {( \frac{Δ [ Oi ]}{Δ P} )}_{act} + \\ δ {Q}_{act} ( {L}_{mi} ) \cdot {( \frac{Δ [ Oi ]}{Δ Q} )}_{act} - {δ [ Oi ]}_{act} ( {L}_{mi} )\end{matrix} \}}^{2}$$

In a case where a change in a growth process parameter can be regarded as being independent of the other parameters, the influence coefficient can be determined in a simpler manner in accordance with Equations (17) to (19).

When the change in the crucible rotation speed can be regarded as being independent, the influence coefficient of the crucible rotation speed can be determined as follows:

$${( \frac{Δ [ Oi ]}{Δ CR} )}_{act} = \frac{1}{K} {\sum }_{i = 1}^{K} \frac{{δ [ Oi ]}_{act} ( {L}_{mi} )}{δ {CR}_{act} ( {L}_{mi} )} \qquad ( 17 )$$

When the change in the pressure in the furnace can be regarded as being independent, the influence coefficient of the pressure in the furnace can be determined as follows:

$${( \frac{Δ [ Oi ]}{Δ P} )}_{act} = \frac{1}{K} {\sum }_{i = 1}^{K} \frac{{δ [ Oi ]}_{act} ( {L}_{mi} )}{δ {P}_{act} ( {L}_{mi} )} \qquad ( 18 )$$

When the change in the inert gas flow rate can be regarded as being independent, the influence coefficient of the inert gas flow rate can be determined as follows:

$${( \frac{Δ [ Oi ]}{Δ Q} )}_{act} = \frac{1}{K} {\sum }_{i = 1}^{K} \frac{{δ [ Oi ]}_{act} ( {L}_{mi} )}{δ {Q}_{act} ( {L}_{mi} )} \qquad ( 19 )$$

Of course, when a change in a growth process parameter can be regarded as being independent, the above-described approach using Equation (16) may also be employed.

Using the influence coefficients determined from recent batches in the above-described manner, the influence coefficients to be used in the setting calculation are modified in accordance with Equations (20) to (22).

$$\begin{matrix}{( \frac{\partial f}{\partial CR} )}_{( n )} = ( 1 - {ω}_{CR} ) {( \frac{\partial f}{\partial CR} )}_{( n - 1 )} + {{ω}_{CR} ( \frac{Δ [ Oi ]}{Δ CR} )}_{act} & ( 20 ) \\ {( \frac{\partial f}{\partial P} )}_{( n )} = ( 1 - {ω}_{p} ) {( \frac{\partial f}{\partial P} )}_{( n - 1 )} + {{ω}_{P} ( \frac{Δ [ Oi ]}{Δ P} )}_{act} & ( 21 ) \\ {( \frac{\partial f}{\partial Q} )}_{( n )} = ( 1 - {ω}_{Q} ) {( \frac{\partial f}{\partial Q} )}_{( n - 1 )} + {{ω}_{Q} ( \frac{Δ [ Oi ]}{Δ Q} )}_{act} & ( 22 )\end{matrix}$$

where ω_{CR}, ω_{P}, and ω_{Q} are smoothing gains having values in the range from 0 to 1. In the case in which the influence coefficients calculated for each batch from the parameters of most recent two batches are used, Equations (23), (24), and (25) described below are used instead of Equations (5), (9), and (13), respectively.

$$\begin{matrix}Δ CR ( i ) = - \frac{{Δ [ Oi ]}_{ err , Bn} ( i )}{{( \frac{\partial f}{\partial CR} )}_{( n )}} & ( 23 ) \\ Δ P ( i ) = - \frac{{Δ [ Oi ]}_{err , Bn} ( i ) + \frac{\partial f}{\partial CR} δ {CR}_{modify} ( {L}_{mi} )}{{( \frac{\partial f}{\partial P} )}_{( n )}} & ( 24 ) \\ Δ Q ( i ) = - \frac{{Δ [ Oi ]}_{err , Bn} ( i ) + \frac{\partial f}{\partial CR} δ {CR}_{modify} ( {L}_{mi} ) + \frac{\partial f}{\partial P} δ {P}_{modify} ( {L}_{mi} )}{{( \frac{\partial f}{\partial Q} )}_{( n )}} & ( 25 )\end{matrix}$$

In the above-described example in which the influence coefficients are calculated for each batch from the parameters of most recent two batches, the crucible rotation speed, the pressure in the furnace, and the inert gas flow rate are respectively employed as the first growth process parameter, the second growth process parameter, and the third growth process parameter. Note that the order of controlling the parameters is not limited to that described above. In a case in which another growth process parameter is employed, an influence coefficient can also be determined in a similar manner.

In the method of controlling the oxygen concentration of a silicon single crystal according to the present embodiment, as described above, a reference batch is selected from already-grown batches, influence coefficients of growth process parameters on the oxygen concentration are determined for each new batch on the basis of data of already-grown batches, learning is performed to determine optimum profiles of growth process parameters so as to eliminate the deviation of the oxygen concentration of the reference batch from a target value of the oxygen concentration, and the growth process parameters such as the crucible rotation speed CR, the pressure in the furnace P, and the inert gas flow rate Q are automatically set according to the optimized profiles.

This technique ensures that the oxygen concentration of a grown silicon single crystal 17 falls within a specified range over the whole length of the crystal. Furthermore, this technique makes it possible to minimize the deviation of the oxygen concentration of single crystals, which can occur due to time-dependent changes in characteristics/conditions of a crystal growth apparatus/environment. Thus, it becomes possible to grow a single crystal 17 having high quality with a high production yield.

Although in the method of controlling the oxygen concentration of a single crystal according to the present embodiment, three growth process parameters, that is, the crucible rotation speed CR, the pressure in the furnace P, and the inert gas flow rate Q are controlled, only one or two of these parameters may be controlled, or, conversely, another growth process parameter may be added to the above three parameters.

Example

An example of a result of growth of silicon single crystals 17 using the method of controlling the oxygen concentration of single crystal according to the present embodiment is described below.

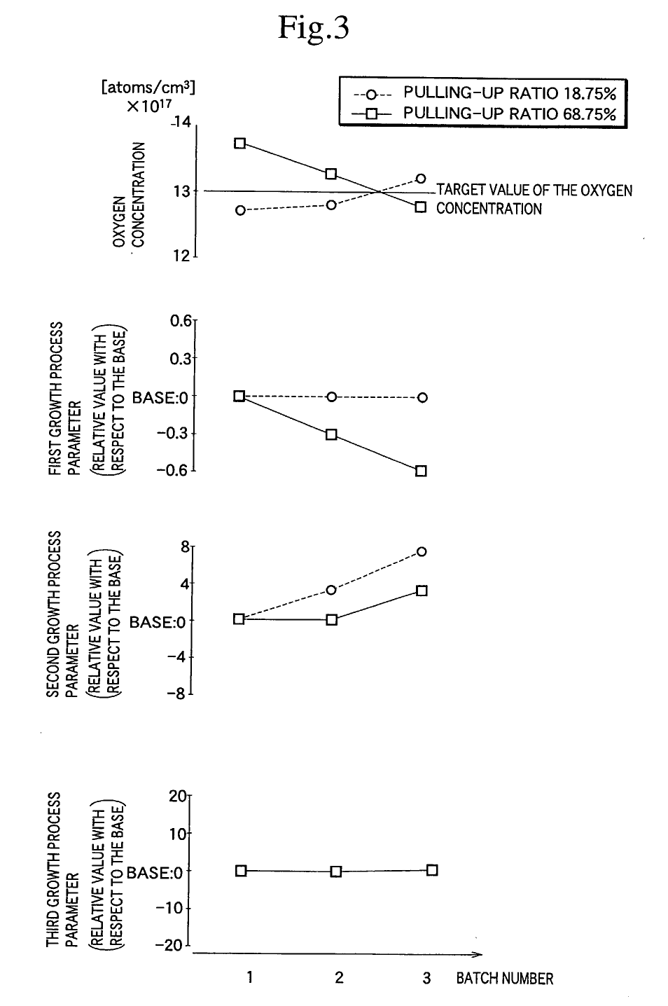

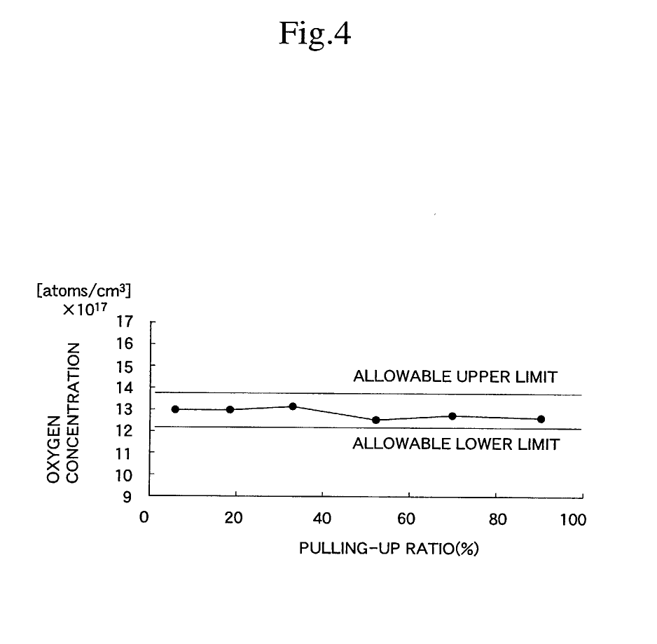

In FIG. 3, batch-to-batch variations in the crucible rotation speed, the pressure in the furnace, and the inert gas flow rate are plotted for the pulling-up ratio of 18.75% and 68.75%, and a batch-to-batch variation in the oxygen concentration is also plotted for the pulling-up ratio of 18.75% and 68.75%. In this example, a raw material of 140 kg was charged and the target value of the oxygen concentration was set to 12.95×10¹⁷ [atoms/cm³]. The diameter of the obtained single crystals was 212 mm. FIG. 4 shows the oxygen concentration of a crystal in the third batch shown in FIG. 3, as a function of the pulling-up ratio. As can be seen from FIG. 4, the oxygen concentration is uniformly controlled over the whole range of the pulling-up ratio.

As can be seen from FIGS. 3 and 4, the method of controlling the oxygen concentration according to the present embodiment makes it possible to minimize the batch-to-batch variation in the oxygen concentration of single crystals and to control the oxygen concentration within a specified range. When another growth process parameter was employed as a control parameter, a similar good result was obtained. In a case in which another furnace was used, a similar good result was also obtained.

In the method/apparatus for controlling the oxygen concentration of a silicon single crystal according to the present invention, as described above, influence coefficients indicating the degrees of influence of growth process parameters on the oxygen concentration are determined for each batch, learning is performed to determine optimum profiles of growth process parameters which would eliminate the deviation of the measured oxygen concentration of the reference batch from a target value, and the growth process parameters are automatically set according to the optimized profiles. This technique ensures that the oxygen concentration of a grown silicon single crystal falls within a specified range over the whole length of the crystal. The deviation of the oxygen concentration of single crystals can be minimized, which can occur due to time-dependent changes in characteristics/conditions of a crystal growth apparatus/environment. Thus, it becomes possible to grow a single crystal having high quality with a high production yield.

Second Embodiment

An embodiment of a method/apparatus for providing guidance for controlling the oxygen concentration of a silicon single crystal according to the present invention is described below with reference to the accompanying drawings. Similar parts to those according to the conventional technique are denoted by similar reference numerals.

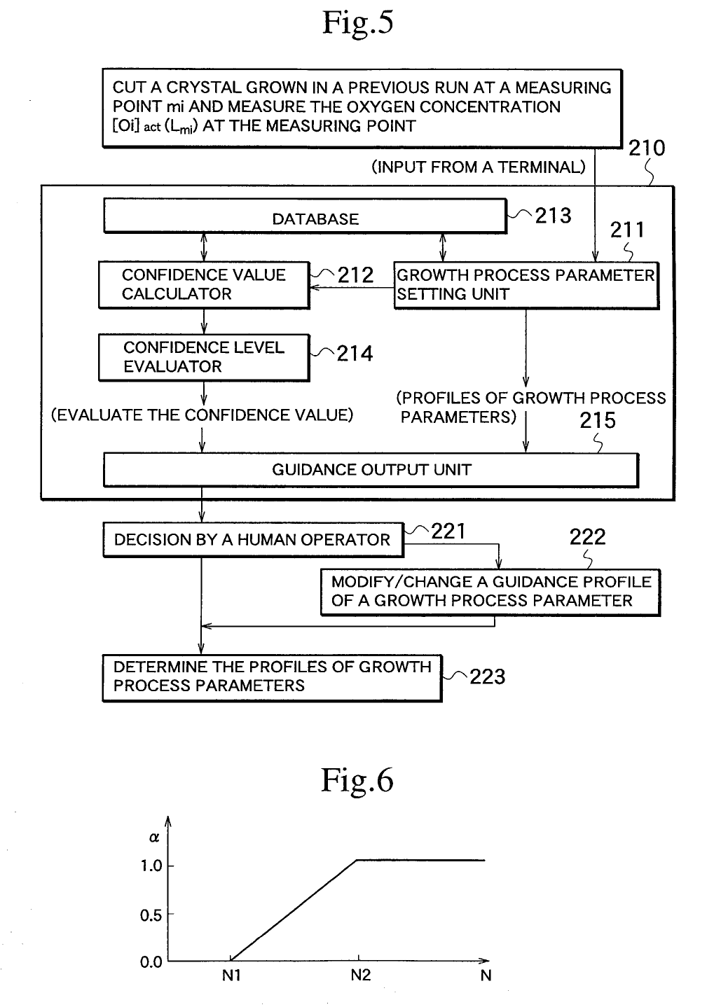

FIG. 1 is a cross-sectional view schematically illustrating a crystal growing apparatus used to grow a silicon single crystal while performing the method of providing guidance for controlling the oxygen concentration of the silicon single crystal according to an embodiment of the present invention. A driving apparatus for driving a crucible 13, a vacuum pump connected to an opening 19, and an inert gas supplying system are connected to an oxygen concentration control guidance apparatus 210 including a growth process parameter setting unit 211, a confidence value calculator 212, a confidence level evaluator 214, a database 213, and a guidance output unit 215, as shown in FIG. 5.

The database 213 stores data indicating parameters which were employed in the past to grow single crystals and also stores data indicating the quality of the grown crystals. The growth process parameter setting unit 211 calculates the profiles of parameters to be employed to grow a next crystal, such as the rotation speed CRₙ₊₁ of the crucible, the pressure Pₙ₊₁ in the furnace, and the flow rate Qₙ₊₁ of the inert gas. The confidence value calculator 212 calculates the confidence value for the profile of a growth process parameter calculated by the growth process parameter setting unit 211, on the basis of an environmental factor and statistical data. The confidence level evaluator 214 evaluates the calculated confidence value. The other parts are similar to those in the conventional crystal growing apparatus 20, and thus they are not described in further detail herein. Thus, a crystal growing apparatus 10 including the oxygen concentration control guidance apparatus 210 and other parts is formed in accordance with the present embodiment.

A process of growing a silicon single crystal using the crystal growing apparatus 10 constructed in the above-described manner while controlling the oxygen concentration of the silicon single crystal is described below with reference to FIG. 5. Before growing a next crystal in the next batch, a batch to be used as a reference batch in the next batch is determined from data stored in the database by taking into account the type of a single crystal to be grown and other conditions. More specifically, on the basis of crystal-type information (such as the serial number, the oxygen concentration specification, and the target value of the oxygen concentration) of the single crystal to be grown, the database is searched for already-grown batches that match the crystal type, and a list of all retrieved batches is produced. The retrieved batches are evaluated in terms of items described below, and the score is calculated for each evaluation item for each batch. A batch having a highest total score is employed as a reference batch.

J(1): Score calculated on the basis of whether the furnace number of a furnace used to grow a crystal in a batch is equal to that to be used.

J(2): Score calculated on the basis of the interval between the date when the previous crystal in the previous batch was grown and a date when a crystal is to be grown.

J(3): Score calculated on the basis of the difference in heater usage period.

J(4): Score calculated on the basis of heater replacement.

J(5): Score calculated on the basis of the difference in usage time of a part.

J(6): Score calculated on the basis of part replacement.

Total score W=ΣJ(i)

Thereafter, the measured oxygen concentration values [Oi]_{act}(Lₘᵢ) at measurement points mi of single crystals of the reference batch are extracted from the database 213. The growth process parameter setting unit 211 calculates the profiles of growth process parameters to be employed in the next growing process, such as the rotation speed CR_{set,n+1} of the crucible, the pressure P_{set,n+1} in the furnace, and the flow rate Q_{set,n+1} of the inert gas, as described below.

In general, the oxygen concentration [Oi] of a silicon single crystal depends on the pulling-up ratio L, the crucible rotation speed CR, the pressure in the furnace P, the inert gas flow rate Q, the melt level GAP, and the crystal rotation speed SR. That is, the oxygen concentration [Oi] is given by Equation (26) described below.

[Oi](L)=f(L, CR, P, Q, GAP, SR) (26)

When a crystal is actually pulled up, the growth process parameters to be controlled are given, in the form of profiles indicating the values of parameters as a function of the pulling-up ratio L, to the control panel of the crystal growing apparatus, and the crystal is pulled up in accordance with the given profiles. Specific examples of profiles of parameters are a profile of the rotation speed of the crucible (CR=CR(L)), a profile of the pressure in the furnace (P=P(L)), a profile of the flow rate of the inert gas (Q=Q(L)), a profile of the melt level (GAP=GAP(L)), and a profile of the rotation speed of crystal (SR=SR(L)). In general, the growth process parameters described above can influence the oxygen concentration, although some of these parameters are not necessary to be varied depending on the pulling-up ratio L. To control the oxygen concentration, the manner of determining the profiles of the respective growth process parameters is important. In the present invention, the profiles to be employed in a crystal growth process are determined on the basis of data of a reference batch in which the crystal have been grown. When a reference batch Bn is given, profiles of parameters of the reference batch Bn, that is, CR_{act,Bn}(L), P_{act,Bn}(L), Q_{act,Bn}(L), GAP_{act,Bn}(L), and SR_{act,Bn}(L) are employed in the next growth process as reference profiles CR_{ref}(L), P_{ref}(L), Q_{ref}(L), GAP_{ref}(L), and SR_{ref}(L).

That is, the respective reference profiles are given as follows:

reference profile of the rotation speed of the crucible: CR_{ref}(L)=CR_{act,Bn}(L),

reference profile of the pressure in the furnace: P_{ref}(L)=P_{act,Bn}(L),

reference profile of the flow rate of the inert gas: Q_{ref}(L)=Q_{act,Bn}(L),

reference profile of the melt level: GAP_{ref}(L)=GAP_{act,Bn}(L), and

reference profile of the rotation speed of crystal: SR_{ref}(L)=SR_{act,Bn}(L).

The measured oxygen concentration values [Oi]_{act} for the reference batch Bn are stored in the database, and a set of a measurement position (=pulling-up ratio), a measured oxygen concentration, and a target value [Oi]ₐᵢₘ of the oxygen concentration is obtained for various measurement positions, as described below in Equation (27).

(Lₘⱼ, [Oi]_{act,Bn}(j), [Oi]_{aim,Bn}(j)) (1≦j≦n) (27)

The oxygen concentration deviation Δ[Oi]ₑᵣᵣ, that is, the measured oxygen concentration−the target value of oxygen concentration, is given by Equation (28) described below.

Δ[Oi]_{err,Bn}(j)=[Oi]_{act,Bn}(j)−[Oi]_{aim,Bn}(j) (1≦j≦n) (28)

When the oxygen concentration [Oi] of a silicon single crystal is a function of the pulling-up ratio L, the crucible rotation speed CR, the pressure in the furnace P, the inert gas flow rate Q, the melt level GAP, and the crystal rotation speed SR, the change in the oxygen concentration [Oi] is given by Equation (29) as described below.

$$Δ f ( L , CR , P , Q , GAP , SR ) = \frac{\partial f}{\partial L} Δ L + \frac{\partial f}{\partial CR} Δ CR + \frac{\partial f}{\partial P} Δ P + \frac{\partial f}{\partial Q} Δ Q + \frac{\partial f}{\partial GAP} Δ GAP + \frac{\partial f}{\partial SR} Δ SR \qquad ( 29 )$$

Although various growth process parameters must be controlled to control the oxygen concentration of a silicon single crystal, controlling of a first growth process parameter u and a second growth process parameter v is discussed herein by way of example. Herein, u, v ∈{CR, P, Q, GAP, . . . ,}. First, the oxygen concentration deviation is tried to be eliminated by optimizing the first growth process parameter by means of learning. This can be achieved when Equation (30) is satisfied, and thus a compensation amount Δu(j) for the first growth process parameter is given by Equation (31). In Equations (30) and (31), ∂f/∂u is the influence coefficient indicating the degree of influence of the first growth process parameter on the oxygen concentration of a crystal. This influence coefficient is experimentally determined in advance or calculated for each batch.

$$\begin{matrix}- {Δ [ Oi ]}_{err , Bn} ( j ) = \frac{\partial f}{\partial u} Δ u & ( 30 ) \\ Δ u ( j ) = \frac{- {Δ [ Oi ]}_{err , Bn} ( j )}{\frac{\partial f}{\partial u}} & ( 31 )\end{matrix}$$

Herein, Δu(j) (j=1, 2, 3, . . . , n) is given only for discrete values of the pulling-up ratio L. Therefore, the compensation value Δu(L) (0≦L≦1) for the profile of the growth process parameter u(L) depending on the pulling-up ratio L is given by a polygonal-line function of the pulling-up ratio L obtained by connecting Δu(j) (j=1, 2, 3, . . . , n) with a polygonal line. In particular, Δu(Lₘⱼ)=Δu(j) for L=Lₘⱼ.

In the following description, the reference profile of the first growth process parameter U_{ref}(L) is assumed to be given by a polygonal-line function. More specifically, the reference profile of the first growth process parameter takes values of u₀, U₁, U₂, . . . , U_{N} when the pulling-up ratio L has values of L₀ (=0), L₁, L₂, . . . , L_{N} (=1), respectively. However, when the pulling-up ratio L has a value other than the above, the reference profile of the first growth process parameter takes a value calculated by means of linear interpolation.

Let uⱼ′=uⱼ+δuⱼ(0≦j≦N), and let u′(L) be the profile of the first growth process parameter. Herein, δuⱼ(0≦j≦N) is selected such that Equation (32) has a minimum value or a value smaller than a predetermined value εᵤ.

$${J}_{u} = {\int }_{0}^{1} {\{ ( {u}_{act , Bn} ( L ) + Δ u ( L ) ) - {u}^{′} ( L ) \}}^{2} ⅆ L \qquad ( 32 )$$

Herein, we introduce a function δu_{modify}(L) which takes values of δu₀, δu₁, δu₂, . . . , δU_{N} when the pulling-up ratio L has values of L0 (=0), L₁, L₂, . . . , L_{N}(=1), and which takes linearly-interpolated values for the other values of the pulling-up ratio L.

The growth process parameter setting unit 211 determines the profile u_{set,n+1}(L) of the first growth process parameter to be employed in the next crystal growth process in accordance with Equation (33) described below.

u_{set,n+1}(L)=u_{act,Bn}(L)+Gᵤ(L)×δu_{modify}(L) (33)

where Gᵤ(L) is a learning control gain (0≦Gᵤ(L)≦1).

Herein, upper and lower limits are predetermined for U_{set,n+1}(L), δu_{modify}(L), and the differential coefficient ∂u_{set,n+1}(L)/∂L of u_{set,n+1}(L) with respect to the pulling-up ratio. If the deviation of the oxygen concentration cannot be completely compensated for by controlling the first growth process parameter because of the above limitations on values, the deviation is further compensated for by controlling the second growth process parameter in the next step.

To eliminate the oxygen concentration deviation by optimizing the second growth process parameter, Equation (34) must be satisfied. Thus a compensation amount Δv(j) for the second growth process parameter is given by Equation (35). In Equations (34) and (35), ∂f/∂v is the influence coefficient indicating the degree of influence of the second growth process parameter on the oxygen concentration of a crystal. This influence coefficient is experimentally determined in advance or calculated for each batch.

$$\begin{matrix}- {Δ [ Oi ]}_{err , Bn} ( j ) = \frac{\partial f}{\partial u} δ {u}_{modify} ( {L}_{mj} ) + \frac{\partial f}{\partial v} Δ v & ( 34 ) \\ Δ v ( j ) = - \frac{{Δ [ Oi ]}_{err , Bn} ( j ) + \frac{\partial f}{\partial u} δ {u}_{modify} ( {L}_{mi} )}{\frac{\partial f}{\partial v}} & ( 35 )\end{matrix}$$

Herein, ΔAv(j) (j=1, 2, 3, . . . , n) is given only for discrete values of the pulling-up ratio L. Therefore, the compensation value Δv(L)(0≦L≦1) for the profile of the growth process parameter v(L) depending on the pulling-up ratio L is given by a polygonal-line function of the pulling-up ratio L obtained by connecting Δv(j) (j=1, 2, 3, . . . , n) with a polygonal line. In particular, Δv(Lₘⱼ)=Δv(j) for L=Lₘⱼ.

In the following description, the reference profile of the first growth process parameter V_{ref}(L) is assumed to be given by a polygonal-line function. More specifically, the reference profile of the second growth process parameter takes values of v₀, v₁, v₂, . . . , v_{N} when the pulling-up ratio L has values of L₀(=0), L₁, L₂, . . . , L_{N}(=1), respectively. However, when the pulling-up ratio L has a value other than the above, the reference profile of the second growth process parameter takes a value calculated by means of linear interpolation.

Let vⱼ′=vⱼ+δvⱼ (0≦j≦N), and let v′(L) be the profile of the second growth process parameter. Herein, δvⱼ(0≦j≦N) is selected such that Equation (36) has a minimum value or a value smaller than a predetermined value εᵥ.

$${J}_{v} = {\int }_{0}^{1} {\{ ( {v}_{act , Bn} ( L ) + Δ v ( L ) ) - {v}^{′} ( L ) \}}^{2} ⅆ L \qquad ( 36 )$$

Herein, we introduce a function δv_{modify}(L) which takes values of δv₀, δv₁, v₂, . . . , δv_{N} when the pulling-up ratio L has values of L₀ (=0), L₁, L₂, . . . , L_{N} (=1), and which takes linearly-interpolated values for the other values of the pulling-up ratio L.

The growth process parameter setting unit 211 determines the profile v_{set,n+1}(L) of the second growth process parameter to be employed in the crystal growth process in accordance with Equation (37) described below.

v_{set,n+1}(L)=v_{act,Bn}(L)+Gᵥ(L)×δv_{modify}(L) (37)

where Gᵥ(L) is a learning control gain (0≦Gᵥ(L)≦1).

Herein, upper and lower limits are predetermined for v_{set,n+1}(L), δv_{modify}(L), and the differential coefficient ∂v_{set,n+1}(L)/∂L of v_{set,n+1}(L) with respect to the pulling-up ratio.

Note that, in the example described above, guidance for controlling the first and second growth process parameters is provided by way of example and not limitation. Guidance information may be provided only for the first growth process parameter, or for three or more growth process parameters.

The confidence value calculator 212 calculates the confidence value for the profiles of growth process parameters obtained above. Herein, the confidence value ω is represented by a numerical value in a range of 0≦ω≦1 as described below.

The confidence value ω is assumed to be dependent on the following three factors:

ω_{A}: confidence factor based on preliminary evaluation (0≦ω_{A}≦1),

ω_{B}: confidence factor based on statistical evaluation of data of already-grown batches (0≦ω_{B}≦1), and

ω_{C}: confidence factor associated with a grow condition factor of a next growth run (0≦ω_{C}≦1).

ω_{A} is obtained by reading a table in which values determined by evaluating data of already-grown crystals for various crystal types and furnace types or each furnace are described.

ω_{B} is obtained as follows.

The data of already-grown crystals is grouped into data segments in accordance with the crystal type and the furnace type or for each furnace, and numerical values Nₙ, N_{g}, N_{b} described below are added to the respective data segments.

Nₙ indicates the total number of batches grown under a condition belonging to a group classified into that segment.

N_{g} indicates the number of batches, of those grown under a condition belonging to the group classified into that segment, which were evaluated to be good in terms of the oxygen concentration.

N_{b} indicates the number of batches, of those grown under a condition belonging to the group classified into that segment, which were evaluated to be bad in terms of the oxygen concentration.

Depending on a batch Bk, Nₙ, N_{g}, and N_{b} are updated in accordance with Equation (38).

$$\begin{matrix}{N}_{n} ( k + 1 ) = {N}_{n} ( k ) + 1 \\ {N}_{g} ( k + 1 ) = {N}_{g} ( k ) + {Δ}_{g , judge} ( {B}_{k} ) \\ {N}_{b} ( k + 1 ) = {N}_{b} ( k ) + ( 1 - {Δ}_{g , judge} ( {B}_{k} ) )\end{matrix} \qquad ( 38 )$$

where Δ_{g,judge}(Bₖ) has a value of 1 when the measured oxygen concentration of the batch Bₖ satisfies Equation (39), but otherwise has a value of 0.

|Δ[Oi]_{err,Bk}(j)|≦ε_{[Oi]}(1≦j≦n) (39)

where ε_{[Oi]} is a constant indicating an allowable maximum deviation of the oxygen concentration. ω_{B} can be written using the above values as described in Equation (40).

ω_{B}=N_{g}/Nₙ (40)

On the other hand, ω_{C} is given by Equation (41).

ω_{C}=ω_{C1}·ω_{C2}·ω_{C3}·ω_{C4}·ω_{C5} (41)

where ω_{C1} is set to J₁₁ if the crystal is of a new type, but otherwise to J₁₂ (=1.0),

ω_{C2} is set to J₂₁ when the heater is replaced for the first time, to J₂₂ for the second time, and to J₂₃ (=1.0) for the second time,

ω_{C3} is set to J₃₂ (=1.0) if the furnace is of the same type, but otherwise to J₃₁,

107 _{C4} is set to J₄₂ (=1.0) if the furnace is the same, but otherwise to J₄₁,

ω_{C5} is set to J₅₁ if the time interval from the last growth run is equal to or longer than 31 days, J₅₂ if the time interval from the last growth run is within the range of 16 to 30 days, J₅₃ if the time interval from the last growth run is in the range of 8 to 15 days, and J₅₄ (=1.0) if the time interval from the last growth run is equal to or shorter than 7 days,

where Jₖ₁ has a value satisfying the following conditions: J₁₁<J₁₂, J₂₁<J₂₂<J₂₃, J₃₁<J₃₂, J₄₁<J₄₂, and J₅₁<J₅₂<J₅₃<J₅₄. Although five factors are taken into consideration in the above example, the factors which should be taken into consideration are not limited to those. Furthermore, data segments may be further segmented.

The confidence value w is represented using factors ω_{A}, ω_{B}, and ω_{C} as shown in Equation (42).

ω={(1−α) ω_{A}+α·ω_{B}}×ω_{C} (42)

In Equation (42), a is a parameter that is varied depending on the number of collected data N as shown in FIG. 6.

The manner of determining the confidence value ω is not limited to that using Equation (42), but the confidence value ω may be calculated in accordance with another type of equation such as an additive equation, a multicative equation, or an equation including both additive and multicative terms. Furthermore, the number of factors is not limited to 3.

The confidence level evaluator 214 evaluates the confidence value ω being within the range of 0≦ω≦1 and outputs a result indicating the level of confidence having an N-level value determined in the manner described below.

First, N values W₀(=0)<W₁<W₂< . . . <W_{N}(=1) are defined. If Wᵢ₋₁<ω<Wᵢ(i=1, 2, . . . , N−1), the confidence level is given by Gᵢ. If W_{N-1}≦ω≦W_{N}, the confidence level is given by G_{N}.

The guidance output unit 215 outputs the profiles of the growth process parameters together with the confidence level G to a CRT terminal or the like. Thus, the guidance information and the confidence level are presented to the human operator via the CRT terminal (221). If the confidence level displayed on the CRT terminal is too low, the human operator modifies or changes the profile of the growth process parameter (222), and determines the final profile of the growth process parameter, which is transmitted to the control panel (223).

Upon receiving the growth process parameter, the control panel activates a vacuum pump to evacuate the inside of the chamber 11 to a specified pressure. Thereafter, the control panel activates the gas supplying system to supply an inert gas at a specified flow rate into the chamber 11. A current is then passed through the heater 14 to heat the crucible 13 thereby forming the melt 15. Thereafter, the seed crystal 16a held on the end of the seed crystal holder 16b suspended by the wire 16c is brought into contact with the surface of the melt 15, and the wire 16c is wound up by the winder 16d while rotating the crucible 13 and the puller 16 at a predetermined rotation speed, thereby solidifying the melt 15 so as to grow a silicon single crystal 17.

In the method of providing guidance for controlling the oxygen concentration of a crystal according to the present embodiment, as described above, the database is searched to select a reference batch from already-grown batches, learning is performed to determine a correction needed to eliminate the deviation of the oxygen concentration of the reference batch from a target value of the oxygen concentration thereby automatically calculating the profile of the growth process parameter such as the crucible rotation speed, the calculated profile of the growth process parameter is displayed as guidance information together with the confidence value or the confidence level indicating the degree of confidence for the guidance information.

This allows a human operator to easily determine, from the displayed confidence level, whether the profile of the growth process parameter given as guidance information is reliable enough. If the confidence level is too low, the human operator modifies or changes the profile of the growth process parameter via the CRT terminal or the like and determines the final profile of the growth process parameter. This technique ensures that the oxygen concentration of a grown silicon single crystal 17 falls within a specified range over the whole length of the crystal. Furthermore, the amount of job performed by the human operator to evaluate the profile of the growth process parameter can be reduced. Thus, it becomes possible to grow a single crystal 17 having high quality with a high production yield.

Example

An example of a result of growth of silicon single crystals 17 using the method of providing guidance for controlling the oxygen concentration of single crystal according to the present embodiment is described below. In this example, the confidence value is evaluated and the evaluation result is represented by one of five confidence levels G₅, G₄, G₃, G₂, and G₁, which are ordered from high to low in level.

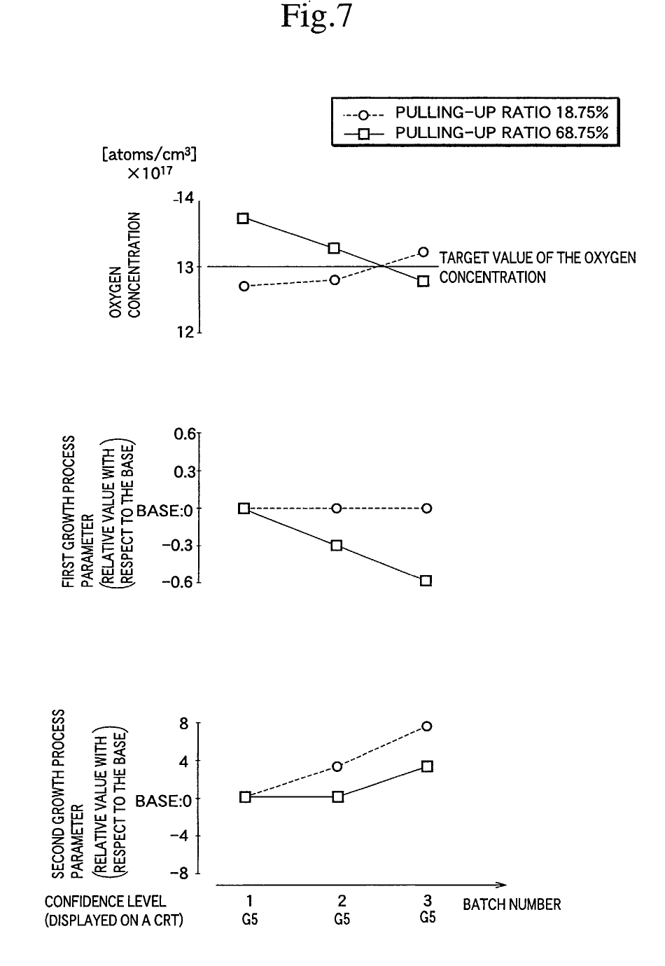

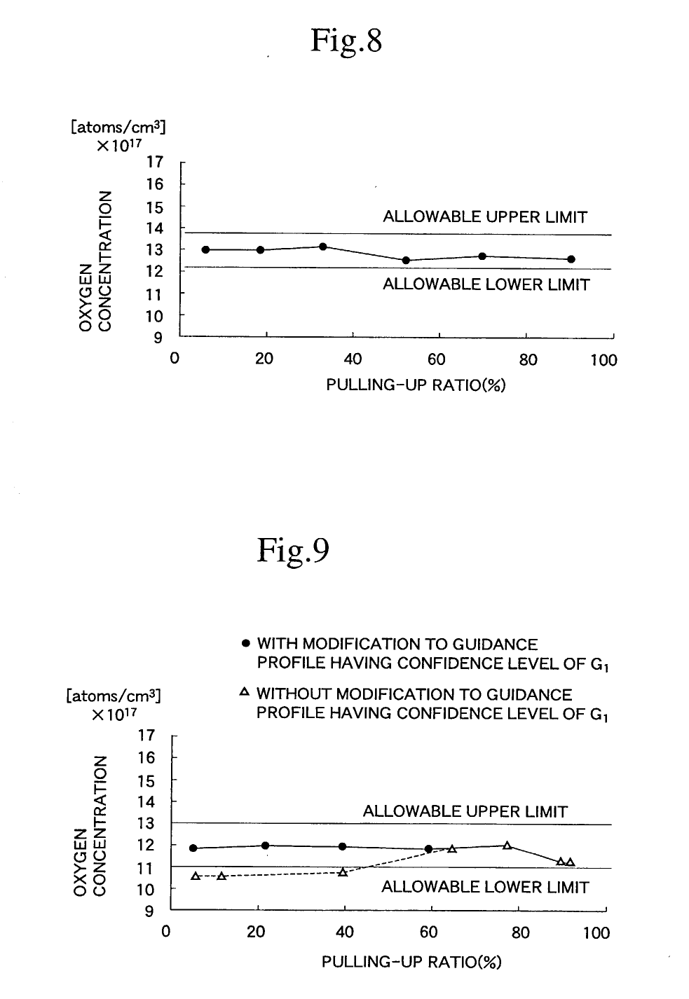

The result is plotted in FIG. 7. That is, FIG. 7 shows batch-to-batch variations in a first growth process parameter and a second growth process parameter, at the pulling-up ratio of 18.75% and 68.75%, which were evaluated to be high in confidence level G₅, and also showing a batch-to-batch variation in oxygen concentration of grown resultant crystals. In this example, a raw material of 140 kg was charged, and the diameter of the obtained single crystals was 212 mm. The target value of the oxygen concentration was set to 12.95×10¹⁷ [atoms/cm³]. As can be seen from FIG. 7, in a case where the confidence level is high, the deviation of the oxygen concentration can be reduced so that the oxygen concentration falls within the specified range, simply by setting the first and second growth process parameter in accordance with the guidance information. FIG. 8 shows the oxygen concentration of a crystal in the third batch shown in FIG. 7, as a function of the pulling-up ratio. As can be seen from FIG. 8, the oxygen concentration is uniformly controlled over the whole range of the pulling-up ratio.

FIG. 9 is a graph showing the oxygen concentration as a function of the pulling-up ratio in the range of 6.25% to 65.6% for a crystal grown using growth process parameters determined by a human operator by modifying, at about ten points, the values of growth process parameters given in guidance information with a confidence level of G₁, and also showing the oxygen concentration which would be obtained if the growth process parameters were set in accordance with the guidance information without making any modification. As can be seen from FIG. 9, when the confidence level for the guidance information is low, good result can be obtained if the proper modification is performed by the human operator. In this example, a raw material of 140 kg was charged and the target value of the oxygen concentration was set to 12.00×10¹⁷ [atoms/cm³]. The diameter of the obtained single crystals was 212 mm.

As can be seen from FIGS. 8 and 9, when the confidence level is high, simply by performing the growth operation in accordance with guidance information, a single crystal having an oxygen concentration controlled within a specified range over the whole length of the crystal can be obtained. In this case, the batch-to-batch variation in the oxygen concentration is also minimized. On the other hand, when the confidence level for the guidance information is low, a warning is given to a human operator. In response to the warning, the human operator can modify or change the parameters given in the guidance information. This makes it possible to prevent the oxygen concentration from deviating from the specified range, and thus a high-quality crystal can be always grown.

If the confidence level for the guidance information is not presented, the human operator must evaluate the given guidance information to determine whether the given guidance information is sufficiently reliable to control the oxygen concentration within the specified range. This would be troublesome for the human operator. Such a troublesome job is eliminated if the human operator is informed of the confidence level and if the confidence level is high enough.

In the method/apparatus for providing guidance for controlling the oxygen concentration of a silicon single crystal according to the present invention, as described above, a reference batch is selected from already-grown batches by searching the database, learning is performed on the profile of control factors in the growth process to obtain an optimum profile by modifying the profile of the control factors employed in the reference batch so as to minimize the deviation of the oxygen concentration of the reference batch from the target value, and the confidence value or the confidence level for the determined profile of the growth parameter is presented to a human operator, thereby allowing a single crystal to be grown without requiring the human operator to do a troublesome job to evaluate the profile of the growth parameter to be employed. This technique ensures that the oxygen concentration of a grown silicon single crystal falls within a specified range over the whole length of the crystal. Thus, in addition to the reduction in the troublesome job performed by the human operator, it also becomes possible to prevent the oxygen concentration of the crystal from deviating from the specified range. Thus, a single crystal having high quality can be grown with a high production yield.

What is claimed is:

1. A method of controlling the oxygen concentration of a silicon single crystal grown using the Czochralski method, comprising the step of, when a growth process condition to be employed in growing a silicon single crystal the next time is determined on the basis of a growth process condition actually used in the past in growing a silicon single crystal, making a correction using an influence coefficient.

2. A method of controlling the oxygen concentration of a silicon single crystal grown using the Czochralski method, comprising the steps of:
preparing a database including data indicating a growth process condition, depending on a crystal length, employed in an already-grown batch and also including data indicating a measured oxygen concentration thereof;
searching the database to select a reference batch, depending on a growth condition to be employed in growing a silicon single crystal the next time;
performing learning on the profile of a control factor in the growth process to obtain an optimum profile by modifying the profile of the control factor employed in the reference batch so as to minimize the deviation of the oxygen concentration from the target value taking into account an influence coefficient indicating the degree of influence of the control factor on the oxygen concentration; and
determining the growth condition to be actually used in growing the silicon single crystal the next time in accordance with the optimized profile.

3. A method of controlling the oxygen concentration of a silicon single crystal grown using the Czochralski method, comprising the steps of:
preparing a database including data indicating a growth process condition, depending on a crystal length, employed in an already-grown batch and also including data indicating a measured oxygen concentration thereof;
searching the database to select a reference batch, depending on a growth condition to be employed in growing a silicon single crystal the next time;
reversely determining an influence coefficient indicating the degree of influence of a control factor on the oxygen concentration of a crystal, from a growth process condition employed in the reference batch and the deviation of a measured oxygen concentration from a target value of the oxygen concentration, thereby correcting the influence coefficient;
performing learning on the profile of a control factor in the growth process to obtain an optimum profile by modifying the profile of the control factor employed in the reference batch so as to minimize the deviation of the oxygen concentration taking into account the corrected influence coefficient; and
determining the growth condition to be actually used in growing the silicon single crystal the next time in accordance with the optimized profile.

4. A method of controlling the oxygen concentration according to one of claims 1 to 3, wherein, as for the crystal-length-dependent growth process condition actually used in the past, one or more conditions are selected from a group consisting of a crystal-length-dependent crucible rotation speed actually employed, a crystal-length-dependent pressure in the furnace actually employed, a crystal-length-dependent inert gas flow rate actually employed, a crystal-length-dependent melt level actually employed, and a crystal-length-dependent crystal rotation speed actually employed.

5. A method of controlling the oxygen concentration according claim 2 or 3, wherein a relational database is used as said database.

6. A method of controlling the oxygen concentration according claim 2 or 3, wherein a database using a flat file is used as said database.

7. An apparatus of controlling the oxygen concentration of a silicon single crystal grown using a Czochralski crystal growth apparatus, comprising:
a database including data indicating a growth process parameter employed in the past to grow a single crystal and also including data indicating the quality of the grown crystal;
an influence coefficient calculator for determining, by means of calculation, an influence coefficient indicating the degree of influence of the growth process parameter on the oxygen concentration, on the basis of a measured oxygen concentration and the growth process parameter actually employed in the past; and
a growth process parameter setting unit for calculating the profile of a growth process parameter such as a crucible rotation speed, a pressure in the furnace, or an inert gas flow rate to be employed in growing a silicon single crystal the next time.

8. A method of providing guidance for controlling the oxygen concentration of a silicon single crystal during a process of growing the silicon single crystal using the Czochralski method in accordance with a method of controlling the oxygen concentration by determining a growth condition to be employed in growing a silicon single crystal the next time by means of modifying a growth condition actually employed in the past for a batch, said method comprising the step of presenting, as guidance information, a reference growth condition obtained by modifying the growth condition employed in the batch, and also presenting the level of confidence for the guidance information.

9. A method of providing guidance for controlling the oxygen concentration of a silicon single crystal during a process of growing the silicon single crystal using the Czochralski method, in accordance with a method of controlling the oxygen concentration, said oxygen concentration method comprising the steps of: preparing a database including data indicating a growth process condition, depending on a crystal length, employed in an already-grown batch and also including data indicating a measured oxygen concentration thereof; searching the database to select a reference batch, depending on a growth condition to be employed in growing a silicon single crystal the next time; and determining the growth condition to be actually employed in growing the silicon single crystal the next time by means of modifying a growth condition actually employed in the past for a batch, said guidance providing method comprising the steps of:
evaluating the confidence level for guidance information in terms of the profile of a growth process parameter, on the basis of data of a silicon single crystal actually grown in the past; and
presenting the confidence level or the confidence value together with said guidance information.

10. An apparatus for providing guidance for controlling the oxygen concentration of a silicon single crystal during a process of growing the silicon single crystal using the Czochralski method, said apparatus comprising:
a database including data indicating a growth process parameter employed in the past to grow a single crystal and also including data indicating the quality of the grown crystal;
a growth process parameter setting unit for calculating the profile of a growth process parameter such as a crucible rotation speed, a pressure in the furnace, or an inert gas flow rate to be employed in growing a silicon single crystal the next time;
a confidence value calculator for calculating the confidence value for the profile of a growth process parameter calculated by the growth process parameter setting unit, on the basis of an environmental factor and statistical data;
a confidence level evaluator for determining the confidence level by evaluating the confidence value calculated by the confidence value calculator; and
a guidance output unit for presenting the confidence value or the confidence level for the profile of the growth parameter together with the profile of the growth process parameter.
